(19) United States
(12) Patent Application Publication
(10) Pub. No.: US 2007/0085592 A1
(43) Pub. Date: Apr. 19, 2007

(54) High-frequency switch circuit, semiconductor device and communication terminal apparatus

(76) Inventors: Eiji Yasuda, Osaka (JP); Tadayoshi Nakatsuka, Osaka (JP); Toshihiro Shougaki, Osaka (JP); Kenichi Hidaka, Osaka (JP); Taketo Kunihisa, Osaka (JP)

Correspondence Address: MCDERMOTT WILL & EMERY LLP, 600 13TH STREET, N.W., WASHINGTON, DC, 20005-3096, US

(21) Appl. No.: 11/518,167

(22) Filed: Sep. 11, 2006

(30) Foreign Application Priority Data
Oct. 17, 2005 (JP) 2005-301582

(51) Int. Cl. H03K 17/687

(52) U.S. Cl. 327/430

(57) ABSTRACT

In a high-frequency switch circuit having a booster circuit and a voltage switch circuit for ON/OFF control of the booster circuit, the voltage switch circuit has a means for gradually dropping the gate input voltage and the drain/source input voltage of a series of FETs over a voltage drop time of 10 μsec or more at the time of switching from a boosted voltage to a non-boosted voltage.

### BACKGROUND OF THE INVENTION

Communication systems of mobile phones have different access methods and radio transmission frequencies from one another according to the standards adopted. To use a mobile phone in various areas in the world, therefore, a user must carry a mobile phone conforming to the standard adopted in each country or area in which the user intends to enjoy the service, or carry one multiband-ready mobile phone supporting a plurality of communication systems. In the latter case, to make one mobile phone ready for a plurality of communication systems, the mobile phone may be constructed of components for the respective systems. However, such a mobile phone will become large in both volume and weight in proportion to the increase of the components, and thus no more be suitable as portable equipment. In view of this, a need arises for a small-size, light-weight high-frequency component supporting a plurality of systems.

Mobile communication terminals such as mobile phones use waves in the GHz band during communication. In such an apparatus, a series of field effect transistors (FETs) using gallium arsenide (GaAs) excellent in frequency characteristic in high frequencies is used as a switching element in an antenna switch circuit, a transmission/reception switch circuit and the like. In the series of FETs, a high-level voltage (for example, 3 V) is applied to a gate voltage terminal as a gate voltage terminal bias sufficiently higher than a pinch-off voltage, for example, to thereby make the drain/source impedance low. In this way, the FETs can be controlled to be in the ON state. In reverse, a low-level voltage (for example, 0 V) is applied to the gate voltage terminal as a gate voltage terminal bias sufficiently lower than the pinch-off voltage, to thereby make the drain/source impedance high. In this way, the FETs can be controlled to be in the OFF state.

An antenna switch for such a mobile phone is required to perform switching of a signal having large power of about 1 W or more. At this switching of a large-power signal, distortion sometimes occurs in the antenna switch using FETs due to input of a large-power transmission signal into the FETs in the ON or OFF state, causing deterioration of the reception sensitivity of the mobile phone. Such unnecessary distortion must be suppressed in the antenna switch using FETs.

One of the most effective methods of suppressing the distortion due to input of a large-power signal described above without increasing the FET size such as increasing the number of stages of FETs is setting the voltage to be applied to the gates of FETs at a value sufficiently lower than the pick-off voltage when the FETs are in the OFF state. This method refers to a method of suppressing distortion by widening the difference in gate voltage condition between the ON and OFF states of FETs. Japanese Laid-Open Patent Publication No. 11-55156 discloses such a method in which a booster circuit is incorporated in an antenna switch to control FETs with a voltage boosted with respect to an external input voltage.

FIG. 12 is a circuit diagram of a switch for high frequencies (high-frequency switch) as a first conventional switch circuit configured as described above. The high-frequency switch performs switching of an output path for an input high-frequency signal. In the first configuration, a single-pole single-throw (SPST) switch is shown for simplification. A first high-frequency signal terminal RF10 is placed at the input side, while a second high-frequency signal terminal RF20 is placed at the output side. A high-frequency signal input into the first high-frequency signal terminal RF10 is output from the second high-frequency signal terminal RF20 (the input/output relationship of the switch may be reversed). Between the first and second high-frequency signal terminals RF10 and RF20, placed are a first field effect transistor (FET) FET1 and a second FET FET2 as a switch circuit for switching of a high-frequency signal path. Hereinafter, it should be noted that FETs refer to a switch circuit using the FITs as a switching element.

As a gate input voltage V101 and a drain/source input voltage V102 for the FETs (FET1 and FET2), a booster circuit output voltage V103 (VCP) (for example, boosted voltage VCP=7 V) obtained by boosting an external supply voltage V11 (for example, power supply voltage VDD=3 V) to a predetermined voltage with an oscillation circuit (OP) 12 and a charge pump of a booster circuit (CP) 13 are used to control ON/OFF of the FETs. A logic circuit (DE) 14 applies the booster circuit output voltage V103 (for example, 7 V) to the FETs in the ON state as a high-level voltage, while applying a low-level voltage (for example, 0 V) to the FETs in the OFF state, according to a logic signal input via an external control input terminal 21, to thereby control the FETs.

Resistances R101 and R102 are connected to the gates of the FETs, and resistances R201, R202 and R203 are provided to fix the potentials at the drains/sources of the FETs.

According to the method described above, the external supply voltage V11 is not supplied as it is as the gate input voltage V101 and the drain/source input voltage V102 for the FETs, but is controlled with the voltage V103 boosted with the booster circuit (CP) 13. As a result, when the number of stages of FETs is the same, a switch having the booster circuit (CP) 13 can obtain higher handling power compared with a switch having no such booster circuit (CP), and in this way, distortion occurring in the FETs can be suppressed. When the same handling power is required, using a boosted voltage can reduce the number of stages of FETs required and thus is effective in reduction of the chip size.

A drawback of such a switch having a booster circuit is increasing the power consumption. The current consumed in the booster circuit and the oscillation circuit increases, compared with a switch circuit having no booster circuit, resulting in increase of the current consumption from about 20 μA to about 200 μA, and this deteriorates the standby time of mobile phones. To solve this problem, Japanese Laid-Open Patent Publication No. 2004-320439 discloses a method of reducing the current consumption by providing a function of keeping a booster circuit OFF during the time of input of small power (for example, during signal reception).

FIG. 13 is a circuit diagram of a high-frequency switch as a second conventional switch circuit configured as described above. In FIG. 13, the first high-frequency signal terminal RF10, the second high-frequency signal terminal RF20, the series of FETs composed of the first and second FETs FET1 and FET2, the gate input voltage V101, the drain/source input voltage V102, the external supply voltage V11, the booster circuit output voltage V103, the external control input terminal 21, the oscillation circuit (OP) 12, the booster circuit (CP) 13 and the logic circuit (DE) 14 are the same as those in FIG. 12.

In the configuration shown in FIG. 13, a voltage switch circuit (SW) 15 for selecting a voltage output and a voltage switch control terminal 31 for controlling the voltage switch circuit (SW) 15 and the oscillation circuit (OP) 12 are added to the components of the high-frequency switch shown in FIG. 12. With this configuration, the voltage to be applied as the gate input voltage V101 and the drain/source input voltage V102 can be switched with the voltage switch circuit (SW) 15. In other words, either the external supply voltage V11 (for example, power supply voltage VDD=3 V) or the booster circuit output voltage V103 (VCP) boosted with the booster circuit (CP) 13 to a predetermined voltage (for example, boosted voltage VCP=7 V) can be selected as a FET selection control voltage V104 to be applied as the gate input voltage V101 and the drain/source input voltage V102.

Since the oscillation circuit (OP) 12 does not operate during the time when the external supply voltage V11 (for example, power supply voltage VDD=3 V) is selected as the FET selection control voltage V104, the current consumption can be reduced.

According to the method described above, the FET selection control voltage V104 is set at the booster circuit output voltage V103 (VCP) during the time of input of large power (for example, during signal transmission) in which suppression of distortion is desired. Contrarily, the FET selection control voltage V104 is set at the external supply voltage V11 during the time of input of small power (for example, during signal reception) in which distortion causes no problem, to enable reduction in current consumption.

However, the booster circuit-incorporated high-frequency switch circuit having the booster circuit ON/OFF function described above as the second conventional configuration has the following problems.

FETs in the ON state become OFF for several tens of microseconds at the time of switching of the booster circuit from ON (for example, boosted voltage VCP=7 V) to OFF (for example, power supply voltage VDD=3 V). In other words, discontinuity arises in a high-frequency signal input into the path between the first and second high-frequency signal terminals RF10 and RF20.

The discontinuity of a high-frequency signal at the time of ON/OFF switching of the booster circuit of the high-frequency switch will be described with reference to timing charts of simulation results shown in FIGS. 14A to 14E. In this simulation, a circuit operating in the manner shown in FIGS. 14A to 14C was used. That is, when a high-level voltage is applied to the voltage switch control terminal 31, the FET selection control voltage V104 is set at the booster circuit output voltage V103 (for example, boosted voltage VCP=7 V), whereas when a low-level voltage is applied to the voltage switch control terminal 31, the FET selection control voltage V104 is set at the external supply voltage V11 (for example, power supply voltage VDD=3 V) (the same phenomenon will result if the voltage switch control terminal 31 operates in reverse).

Conventionally, in implementation of a booster circuit-incorporated high-frequency switch having the booster circuit ON/OFF function, the FET gate voltage is made to drop within a voltage drop time of 1 μsec or less at the time of switching of the booster circuit from ON (VCP) to OFF (VDD), as shown as the gate input voltage and the drain/source input voltage in FIGS. 14B and 14C, since no delay circuit is especially provided. In this voltage drop time of 1 μsec or less, however, the drain/source voltage drop is evidently delayed behind the gate voltage drop at the time of switching of the signal to the FET gate by switching the booster circuit from ON to OFF, as shown in the timing charts of the FET gate potential and drain/source potential in FIGS. 14B and 14C.

The above delay occurs because a current flows in a FET in one direction from the gate to the drain/source with respect to the voltage fluctuation arising with ON (VCP) to OFF (VDD) of the booster circuit. This delay time may be reduced by reducing the resistance value of the potential fixing resistance R201, R202, R203 connected to the drains/sources. However, a leak occurs in the high-frequency signal with decrease of the resistance values. Basically, therefore, it is impossible to eliminate the delay time of the drain/source potential.

If the potential fixing resistance is omitted, there will be no escape of charge that has flowed from the gate to the drain/source, and this will considerably increase the delay time. More specifically, at the time of switching of the booster circuit from ON (VCP) to OFF (VDD), the FET will be in the state in which the potential is lower at the gate than at the drain/source, that is, the gate-drain/source voltage Vgs shown in FIG. 14D is reverse-biased, for the time of several tens of milliseconds. If this reverse bias is lower than a pinch-off voltage Vp, the FET will inevitably be turned OFF as shown in FIG. 14E as RF10-RF20 insertion loss.

### SUMMARY OF THE INVENTION

An object of the present invention is providing a booster circuit-incorporated high-frequency switch circuit having the booster circuit ON/OFF function, in which no discontinuity of a high-frequency signal occurs at the time of switching of the booster circuit from ON to OFF.

The first high-frequency switch circuit of the present invention includes: a series of field effect transistors having a plurality of field effect transistors connected in series between input/output terminals of a high-frequency signal path permitting passing of a plurality of high-frequency signals different in frequency, a control voltage input terminal connected to gates of the plurality of field effect transistors to permit input of a control input signal for controlling ON/OFF of the plurality of field effect transistors, and a potential fixing connection terminal connected to drains and sources of the plurality of field effect transistors for fixing potentials at the drains and sources of the plurality of field effect transistors; an oscillation circuit for oscillating an input external supply voltage; a booster circuit for boosting the external supply voltage supplied from the oscillation circuit; and a voltage selection circuit for switching a boosted voltage boosted with the booster circuit and a non-boosted voltage free from boosting with the booster circuit to each other and outputting the resultant voltage to the control voltage input terminal and the potential fixing connection terminal, wherein the voltage selection circuit has means for delaying voltage drop at the control voltage input terminal and the potential fixing connection terminal at the time of switching from the boosted voltage to the non-boosted voltage.

According to the first high-frequency switch circuit of the present invention, it is possible to suppress the delay of the voltage drop at the drains/sources behind the voltage drop at the gates at the time of ON/OFF switching. Therefore, the FET reverse bias can be kept higher than the pinch-off voltage Vp during this switching, and thus discontinuity of a high-frequency signal can be suppressed.

In the first high-frequency switch circuit of the present invention, the means for delaying voltage drop may be means in which the voltage drop at the control voltage input terminal and the potential fixing connection terminal is allowed to occur gradually over a given voltage drop time.

In the first high-frequency switch circuit of the present invention, the means for delaying voltage drop may be a RC delay circuit for outputting a delay signal delayed according to a time constant of a RC time constant circuit composed of a resistance and a capacitance.

In the first high-frequency switch circuit of the present invention, the means for delaying voltage drop may be a gate delay circuit composed of gate delay of a semiconductor device.

In the first high-frequency switch circuit of the present invention, the means for delaying voltage drop may be means in which the voltage drop at the control voltage input terminal and the potential fixing connection terminal is allowed to occur with a given delay time.

In the first high-frequency switch circuit of the present invention, the voltage selection circuit may include a first voltage selection circuit and a second voltage selection circuit, the first voltage selection circuit may have first delay means for delaying voltage drop at the control voltage input terminal, the second voltage selection circuit may have second delay means for delaying voltage drop at the potential fixing connection terminal, and a delay time with the first delay means may be greater than a delay time with the second delay means.

In the first high-frequency switch circuit of the present invention, the first and second delay means may be RC delay circuits for outputting a delay signal delayed according to a time constant of a RC time constant circuit composed of a resistance and a capacitance.

In the first high-frequency switch circuit of the present invention, the first and second delay means may be gate delay circuits composed of gate delay of a semiconductor device.

The second high-frequency switch circuit of the present invention includes: a series of field effect transistors having a plurality of field effect transistors connected in series between input/output terminals of a high-frequency signal path permitting passing of a plurality of high-frequency signals different in frequency, a control voltage input terminal connected to gates of the plurality of field effect transistors to permit input of a control input signal for controlling ON/OFF of the plurality of field effect transistors, and a potential fixing connection terminal connected to drains and sources of the plurality of field effect transistors to fix potentials at the drains and sources of the plurality of field effect transistors; an external supply voltage input terminal at which an external supply voltage is supplied; an oscillation circuit for oscillating the external supply voltage supplied from the external supply voltage input terminal; a booster circuit connected to the control voltage input terminal and the potential fixing connection terminal for boosting the external supply voltage supplied from the oscillation circuit; a voltage switch control terminal receiving a signal for switching the oscillation circuit to OFF at the time of switching of the booster circuit from ON to OFF; and a diode connected between the booster circuit and the external supply voltage input terminal.

According to the second high-frequency switch circuit of the present invention, it is possible to suppress the delay of the voltage drop at the drains/sources behind the voltage drop at the gates at the time of ON/OFF switching. Therefore, the FET reverse bias can be kept higher than the pinch-off voltage Vp during this switching, and thus discontinuity of a high-frequency signal can be suppressed.

In the second high-frequency switch circuit of the present invention, the series of field effect transistors may be constructed of a plurality of multi-gate field effect transistors.

In the second high-frequency switch circuit of the present invention, the series of field effect transistors may be constructed of a plurality of gallium arsenic field effect transistors.

The semiconductor device of the present invention includes the first or second high-frequency switch circuit of the present invention integrated on one semiconductor substrate.

Alternatively, the semiconductor device of the present invention includes the first or second high-frequency switch circuit of the present invention integrated into one package.

The communication terminal apparatus of the present invention includes: the first or second high-frequency switch circuit of the present invention; and a transmission/reception separator connected to the high-frequency switch circuit, wherein the transmission/reception separator switches transmission and reception of a signal to and from the high-frequency switch circuit to each other.

The communication terminal apparatus of the present invention may further includes: a power amplifier connected to the transmission/reception separator; and a DC-DC converter for supplying a voltage to the power amplifier, wherein the power amplifier amplifies power of a signal transmitted to the transmission/reception separator, and the high-frequency switch circuit is voltage-controlled with the DC-DC converter.

The communication terminal apparatus of the present invention may further includes: a low-noise amplifier connected to the transmission/reception separator; and a radio frequency integrated circuit connected to the power amplifier and the low-noise amplifier.

In the communication terminal apparatus of the present invention, at least two of the high-frequency switch circuit, the transmission/reception separator, the power amplifier, the DC-DC converter, the low-noise amplifier and the radio frequency integrated circuit may be mounted on one semiconductor substrate.

In the communication terminal apparatus of the present invention, at least two of the high-frequency switch circuit, the transmission/reception separator, the power amplifier, the DC-DC converter, the low-noise amplifier and the radio frequency integrated circuit may be integrated into one package.

In the communication terminal apparatus of the present invention, at switching of the booster circuit from ON to OFF, a transmission signal input into the high-frequency switch circuit from the transmission/reception separator may be switched to OFF before the booster circuit is switched to OFF, and at switching of the booster circuit from OFF to ON, the transmission signal input into the high-frequency switch circuit from the transmission/reception separator may be switched to ON after the booster circuit is switched to ON.

### BRIEF DESCRIPTION OF THE DRAWINGS

FIG. 1 is a circuit diagram of a high-frequency switch circuit of Embodiment 1 of the present invention.

FIGS. 2A to 2E are timing charts showing the operations of circuits at the time of ON/OFF switching of a booster circuit in the high-frequency switch circuit of Embodiment 1.

FIG. 3A is a circuit diagram of a conventional general voltage switch circuit (SW) in a high-frequency switch circuit, and FIG. 3B is a circuit diagram of a delay circuit-incorporated voltage switch circuit (TDSW) in Embodiment 1.

FIGS. 4A to 4D are circuit diagrams showing examples of delay circuits.

FIG. 5 is a circuit diagram of a high-frequency switch circuit of Embodiment 2 of the present invention.

FIG. 6 is a circuit diagram of a high-frequency switch circuit of Embodiment 3 of the present invention.

FIGS. 7A to 7E are timing charts showing the operations of circuits at the time of ON/OFF switching of a booster circuit in the high-frequency switch circuit of Embodiment 3.

FIG. 8 is a circuit diagram of a communication terminal apparatus of Embodiment 4 of the present invention.

FIGS. 9A and 9B are timing charts of an input voltage at a voltage switch control terminal 31 and a transmission signal TX in the communication terminal apparatus of Embodiment 4.

FIG. 10 is a circuit diagram of a communication terminal apparatus of Embodiment 5 of the present invention.

FIG. 11 is a circuit diagram of a communication terminal apparatus of Embodiment 6 of the present invention.

FIG. 12 is a circuit diagram of a conventional high-frequency switch.

FIG. 13 is a circuit diagram of another conventional high-frequency switch.

FIGS. 14A to 14E are views showing conventional timing charts of simulation results.

### DESCRIPTION OF THE PREFERRED EMBODIMENTS

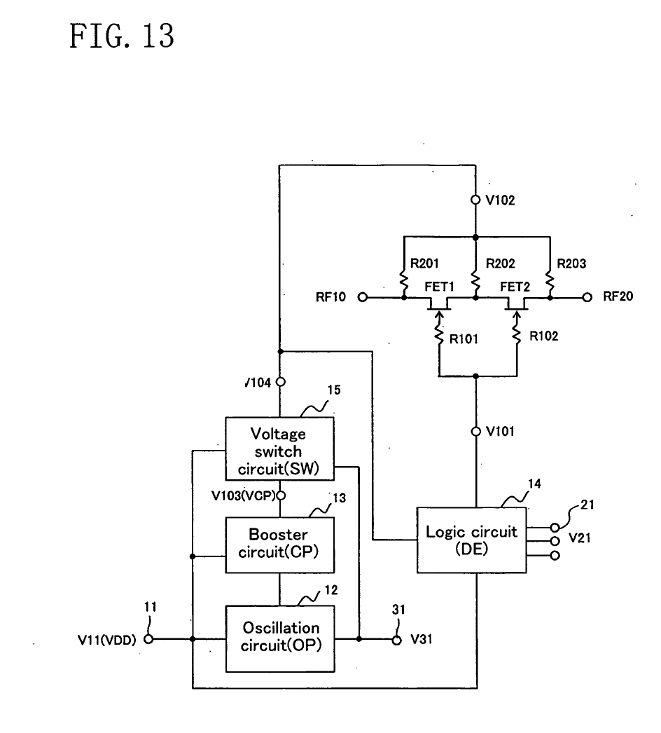

Hereinafter, preferred embodiments of the present invention will be described with reference to the accompanying drawings. It should be noted that in the drawings referred to in the embodiments to follow, components having equivalent functions to those of the conventional circuit shown in FIG. 13 are denoted by the same reference numerals.

### Embodiment 1

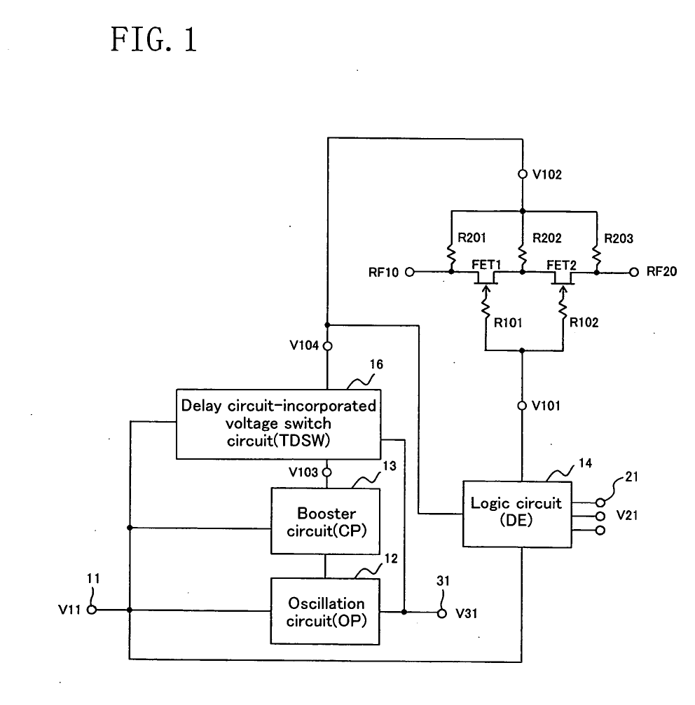

FIG. 1 is a circuit diagram of a high-frequency switch circuit of Embodiment 1 of the present invention. The high-frequency switch circuit of FIG. 1 includes a first high-frequency signal terminal RF10, a second high-frequency signal terminal RF20, a series of FETs including a first field effect transistor (FET) FET1 and a second FET FET2, an external supply voltage terminal 11, an external control input terminal 21, a voltage switch control terminal 31, an oscillation circuit (OP) 12, a booster circuit (CP) 13 and a logic circuit (DE) 14. An external supply voltage V11 is applied to the external supply voltage terminal 11, an external control voltage V21 is applied to the external control input terminal 21, and a voltage switch voltage V31 is applied to the voltage switch control terminal 31. A gate input voltage V101, a drain/source input voltage V102, a booster circuit output voltage V103 and a FET selection control voltage V104 are voltages applied at relevant points of the circuit.

The source/drain of the first FET FET1 and the source/drain of the second FET FET2 are connected in series between the first and second high-frequency signal terminals RF10 and RF20. The gate of the first FET FET1 is connected to the logic circuit 14 via a resistance R101, while the gate of the second FET FET2 is connected to the logic circuit 14 via a resistance R102. The logic circuit 14 is connected to the external control input terminal 21.

The configuration shown in FIG. 1 further includes a delay circuit-incorporated voltage switch circuit (TDSW) 16 for selecting a voltage output, in place of the voltage switch circuit (SW) 15 in the high-frequency switch circuit of FIG. 13.

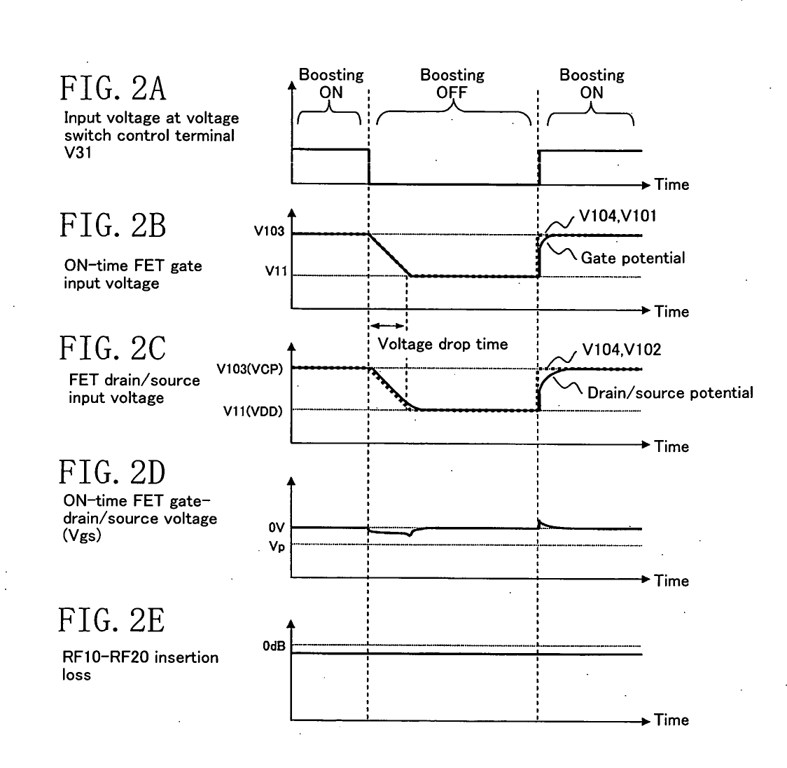

FIGS. 2A to 2E are timing charts showing the operations of the circuits at the time of ON/OFF switching of the booster circuit in the high-frequency switch circuit of Embodiment 1.

In Embodiment 1, as shown in FIG. 2A, ON/OFF of the booster circuit 13 is controlled with the change of the value of the voltage V31 applied to the voltage switch control terminal 31. As shown in FIGS. 2B and 2C, the gate input voltage and the drain/source voltage of FET1 and FET2 are set to have a voltage drop time of 10 μsec or more at the time of switching from the boosted voltage (VCP) to the power supply voltage (VDD), to allow gradual voltage drop over the time. More specifically, in the conventional configuration without the delay circuit-incorporated voltage switch circuit 16, the drop of the drain/source potential is delayed behind the drop of the gate input voltage, which is within 1 μsec, at the time of switching of the booster circuit (CP) of the high-frequency switch circuit from ON (VCP) to OFF (VDD). In this embodiment, however, both the gate input voltage and the drain/source potential are set to have a voltage drop time of 10 μsec or more, for example, to allow gradual voltage drop.

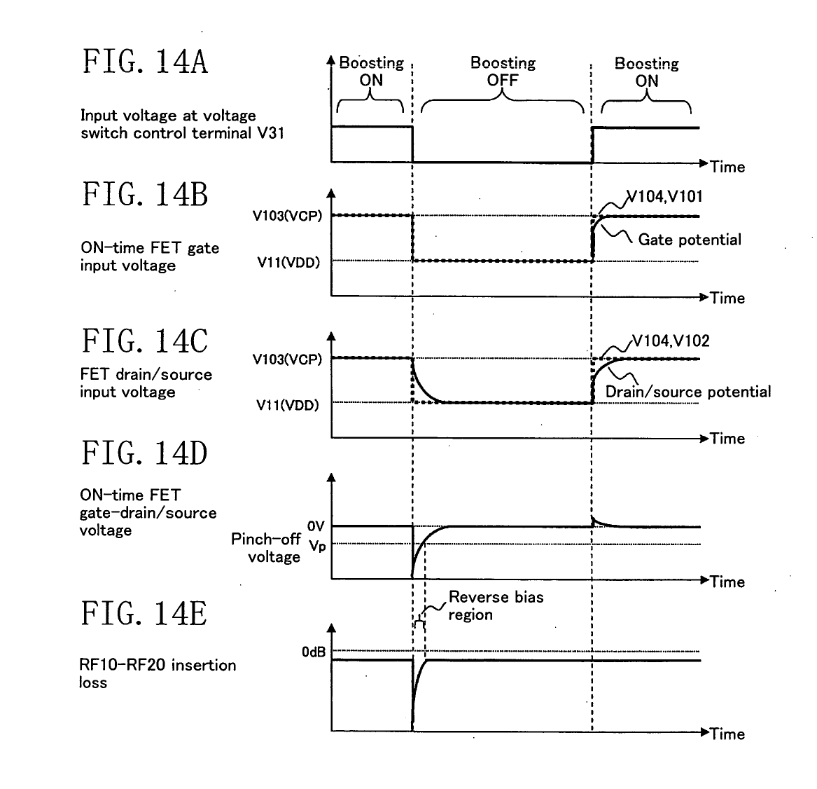

Thus, it is found that the timing at which the gate input voltage drops (voltage drop rate) shown in FIG. 2B follows the timing at which the drain/source potential drops (voltage drop rate) shown in FIG. 2C, unlike the conventional case. As a result, the reverse bias of the gate-drain/source voltage Vgs shown in FIG. 2D is significantly reduced compared with the conventional case (see FIG. 14D), with the gate-drain/source voltage Vgs being kept from becoming lower than the pinch-of voltage Vp at the switching from the boosted voltage (VCP) to the power supply voltage (VDD). Accordingly, it is found that the discontinuity of a high-frequency signal, conventionally occurring in FETs as shown in FIG. 14E, has been eliminated as shown in FIG. 2E.

In other words, in Embodiment 1, a high-frequency switch circuit free from discontinuity of a high-frequency signal, which may otherwise occur at the time of ON/OFF switching of the booster circuit (CP) 13, can be implemented by providing a means for giving a voltage drop time to the gate input voltage and the drain/source input voltage.

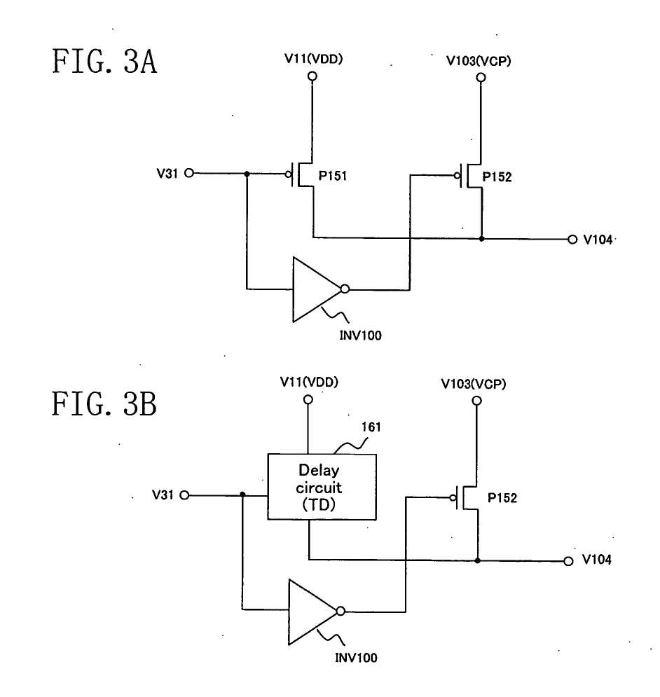

FIG. 3A shows a conventional general voltage switch circuit (SW) in a high-frequency switch circuit, and FIG. 3B shows a delay circuit-incorporated voltage switch circuit (TDSW) in Embodiment 1. As shown in FIG. 3A, the conventional voltage switch circuit (SW) includes P-channel transistors P151 and P152 and an inverter circuit INV100 composed of a P-channel transistor and an N-channel transistor. The gate of the P-channel transistor P151 is connected to the voltage switch control terminal 31, while the gate of the P-channel transistor P152 is connected to the voltage switch control terminal 31 via the inverter circuit INV100. The external supply voltage V11 and the booster circuit output voltage V103 are respectively supplied to the sources of the P-channel transistors P151 and P152. The FET selection control voltage V104 is connected to the drains of the P-channel transistors P151 and P152.

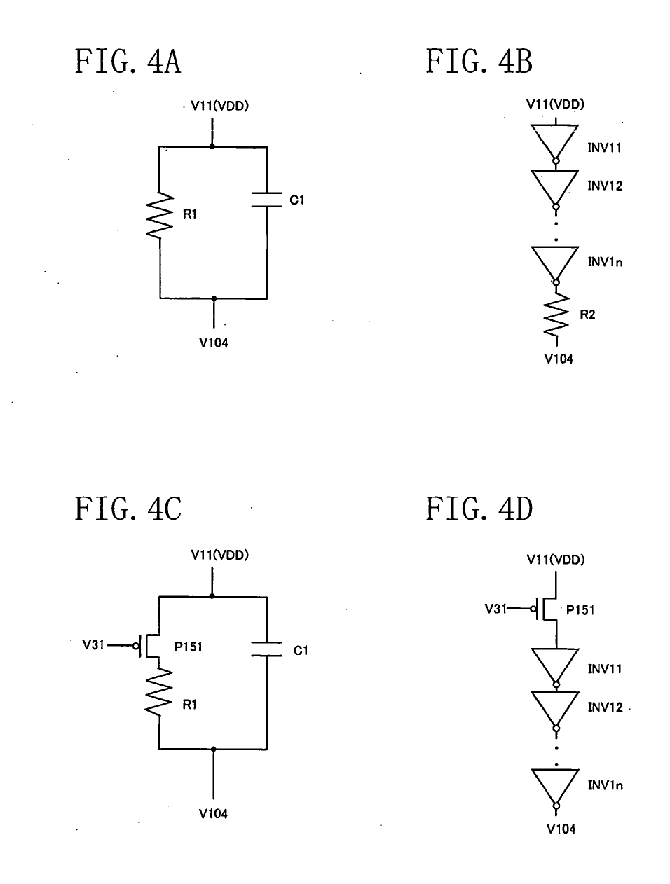

The delay circuit-incorporated voltage switch circuit in Embodiment 1 of the present invention shown in FIG. 3B includes a delay circuit (TD) 161 in place of the P-channel transistor P151 in FIG. 3A. The delay circuit (TD) 161 gives a delay time when the booster circuit changes from ON to OFF. Examples of the delay circuit (TD) 161 are shown in FIGS. 4A to 4D. FIG. 4A shows a delay circuit in which a resistance R1 and a capacitance C1 are connected in parallel, and FIG. 4B shows a delay circuit in which a resistance R2 and an even number of inverters INV11 to INV1n are connected in series to make use of gate delay of the inverters. In the structures shown in FIGS. 4A and 4B, if the resistance value of the resistance R1, R2 is sufficiently large, little current flows to the delay circuit 161 when a high-level voltage is applied to the voltage switch control terminal 31, that is, when the booster circuit output voltage V103 is output. Therefore, the booster circuit output voltage V103 is output with little voltage drop. At the time of switching of the booster circuit 13 from ON to OFF, the FET selection control voltage V104 is changed from the booster circuit output voltage V103 (for example, boosted voltage VCP=7 V) to the external supply voltage V11 (for example, power supply voltage VDD=3 V) after the lapse of the delay time set with the delay circuit (TD) 161. In view of this, the structures shown in FIGS. 4A and 4B are especially useful when the resistance value of the resistance R1, R2 is sufficiently large. When the resistance value of the resistance R1, R2 is not sufficiently large, a P-channel transistor P151 may be provided as shown in FIGS. 4C and 4D, to prevent drop of the boosted voltage.

A specific operation of the voltage switch circuit in Embodiment 1 will be described. In the conventional configuration shown in FIG. 3A, when a low-level voltage is applied to the voltage switch circuit control terminal 31, the P-channel transistor P151 is turned ON and the P-channel transistor P152 is turned OFF, to allow the external supply voltage V11 (for example, power supply voltage VDD=3 V) to be output as the FET selection control voltage V104. Contrarily, when a high-level voltage is applied to the voltage switch circuit control terminal 31, the P-channel transistor P151 is turned OFF and the P-channel transistor P152 is turned ON, to allow the booster circuit output voltage V103 (for example, boosted voltage VCP=7 V) to be output as the FET selection control voltage V104.

In the configuration of Embodiment 1 shown in FIG. 3B, in which the delay circuit (TD) 16 is provided in place of the P-channel transistor P151 shown in FIG. 3A, the voltage is changed with a delay time set with the delay circuit (TD) 161 at the time of switching of the booster circuit 13 from ON to OFF, that is, when the FET selection control voltage V104 is switched from the booster circuit output voltage V103 (for example, boosted voltage VCP=7 V) to the external supply voltage V11 (for example, power supply voltage VDD=3 V).

As described above, in Embodiment 1, in which the delay circuit is incorporated in the voltage switch circuit, the gate input voltage and the drain/source input voltage can be made to shift as shown in the timing charts of FIGS. 2B and 2C. Thus, a high-frequency switch circuit free from discontinuity of a high-frequency signal at the time of ON/OFF switching of the booster circuit can be implemented.

Also, by securing a sufficiently large resistance value in the delay circuit 161, the number of transistors in the delay circuit-incorporated voltage switch circuit 16 can be reduced, and thus the chip area can be reduced.

### Embodiment 2

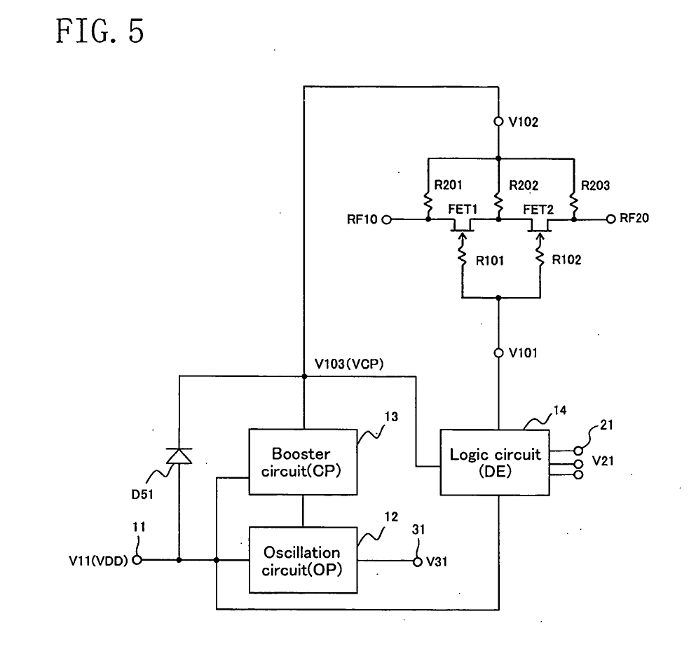

FIG. 5 is a circuit diagram of a high-frequency switch circuit of Embodiment 2 of the present invention. The high-frequency switch circuit of FIG. 5 includes a first high-frequency signal terminal RF10, a second high-frequency signal terminal RF20, a series of FETs including a first FET FET1 and a second FET FET2, an external supply voltage terminal 11, an external control input terminal 21, a voltage switch control terminal 31, an oscillation circuit (OP) 12, a booster circuit (CP) 13 and a logic circuit (DE) 14. An external supply voltage V11 is applied to the external supply voltage terminal 11, an external control voltage V21 is applied to the external control input terminal 21, and a voltage switch voltage V31 is applied to the voltage switch control terminal 31. A gate input voltage V101, a drain/source input voltage V102, a booster circuit output voltage V103 and a FET selection control voltage V104 are voltages applied at relevant points in the circuit.

The configuration shown in FIG. 5 further includes a diode D51 in place of the delay circuit-incorporated voltage switch circuit (TDSW) 16 in FIG. 1. The diode D51 is connected between the external supply voltage terminal 11 and a portion to which the booster circuit output voltage V103 is applied. In the high-frequency switch circuit of this embodiment, which omits the delay circuit-incorporated voltage switch circuit (TDSW) 16. the FETs are controlled directly with the voltage output from the booster circuit 13.

The operation in Embodiment 2 will be described with reference to FIG. 5. When a low-level voltage is applied to the voltage switch control terminal 31 shown in FIG. 5, the oscillation circuit (OP) 12 is turned OFF. As a result, charge stored in a capacitance in the booster circuit (CP) 13 is gradually used, and thus the booster circuit output voltage V103 drops from the boosted voltage VCP toward 0 V. However, since the portion to which the booster circuit output voltage V103 is applied is connected to the external supply voltage V11 via the diode D51, the voltage drop of the booster circuit output voltage V103 stops at a voltage obtained by subtracting a voltage drop at the diode D51 (for example, about 0.7 V) from the external supply voltage V11 (VDD−0.7 V).

In comparison with the configuration in Embodiment 1, the configuration of FIG. 5 includes the diode D51 provided between the external supply voltage terminal 11 and the portion to which the booster circuit output voltage V103 is applied. With this configuration, the following occurs when the booster circuit (CP) 13 is switched from ON to OFF. The oscillation circuit (OP) 12 is turned OFF with the voltage switch control terminal 31, and this causes stored charge to be gradually used. The booster circuit output voltage V103, that is, the FET control voltage then changes from the booster circuit output voltage (VCP) to the voltage obtained by subtracting the voltage drop at the diode D51 from the external supply voltage V11 (VDD−0.7 V) over a delay time during which the charge is gradually used.

In other words, in Embodiment 2, by giving a delay time during which the charge in the booster circuit is gradually used, the gate input voltage and the drain/source input voltage can be changed according to the timing charts shown in Embodiment 1. Thus, a high-frequency switch circuit free from discontinuity of a high-frequency signal at the time of ON/OFF switching of the booster circuit (CP) 13 can be implemented.

Also, since the delay time can be given only by adding the diode, the number of elements such as transistors can be significantly reduced, and thus the chip area can be reduced.

### Embodiment 3

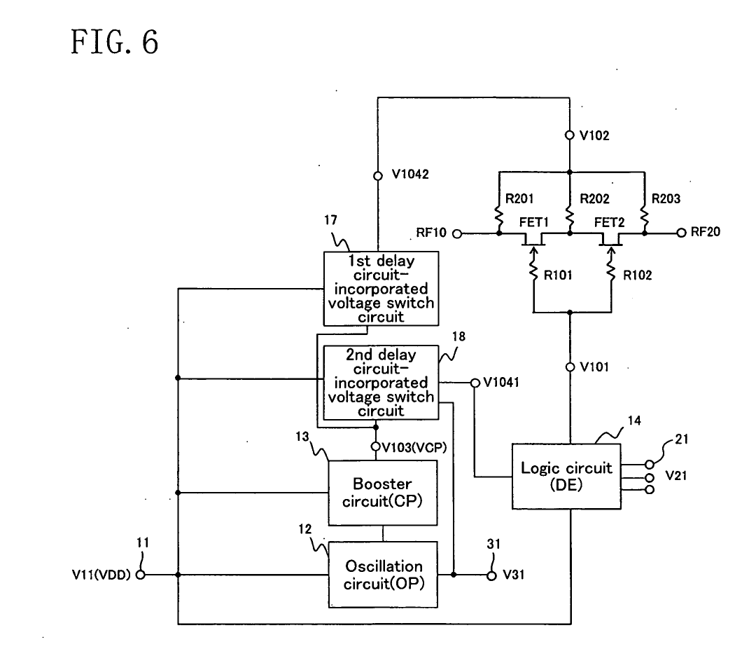

FIG. 6 is a circuit diagram of a high-frequency switch circuit of Embodiment 3 of the present invention. The high-frequency switch circuit of FIG. 6 includes a first high-frequency signal terminal RF10, a second high-frequency signal terminal RF20, a series of FETs including a first FET FET1 and a second FET FET2, an external supply voltage terminal 11, an external control input terminal 21, a voltage switch control terminal 31, an oscillation circuit (OP) 12, a booster circuit (CP) 13 and a logic circuit (DE) 14. An external supply voltage V11 is applied to the external supply voltage terminal 11, an external control voltage V21 is applied to the external control input terminal 21, and a voltage switch voltage V31 is applied to the voltage switch control terminal 31. A gate input voltage V101, a drain/source input voltage V102, a FET drain/source selection control voltage V1042, a booster circuit output voltage V103 and a FET gate selection control voltage V1041 are voltages applied at relevant points in the circuit.

The configuration shown in FIG. 6 further includes a first delay circuit-incorporated voltage switch circuit (TDSW) 17 for application of the drain/source input voltage V102 and a second delay circuit-incorporated voltage switch circuit (TDSW) 18 for application of the gate input voltage V101, in place of the delay circuit-incorporated voltage switch circuit (TDSW) 16 in FIG. 1. The first delay circuit-incorporated voltage switch circuit (TDSW) 17 is connected to a point to which the booster circuit output voltage V103 is applied, a point to which the FET drain/source selection control voltage V1042 is applied and the external supply voltage terminal 11. The second delay circuit-incorporated voltage switch circuit (TDSW) 18 is connected to the external supply voltage terminal 11, a point to which the FET gate selection control voltage V1041 is applied and a point to which the booster circuit output voltage V103 is applied.

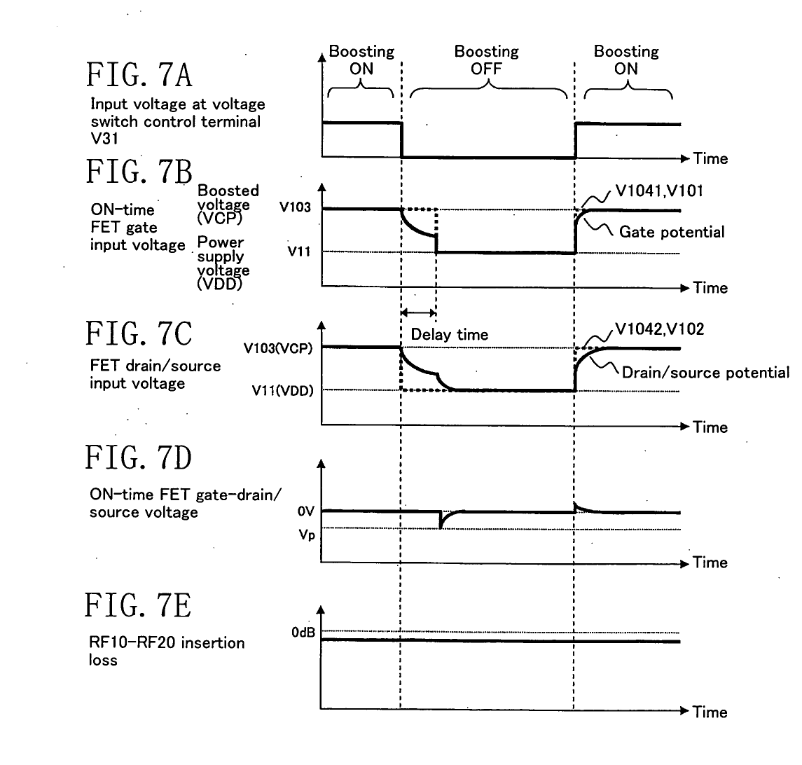

FIGS. 7A to 7E are timing charts showing the operations of the circuits at the time of ON/OFF switching of the booster circuit in the high-frequency switch circuit of Embodiment 3.

In Embodiment 3, when the booster circuit (CP) 13 is switched from ON (VCP) to OFF (VDD) at the timing shown in FIG. 7A, the gate input voltage and the drain/source voltage drop over a delay time of 10 μsec or more as shown in FIGS. 7B and 7C.

Therefore, the time during which the drain/source potential is lower than the gate potential can be reduced as shown in FIGS. 7B and 7C, and thus the reverse bias of the gate-drain/source voltage Vgs shown in FIG. 7D can be significantly reduced compared with the conventional case. Thus, there is not found at all any time in which the gate-drain/source voltage Vgs is lower than the pinch-off voltage Vp at the time of switching from the boosted voltage (VCP) to the power supply voltage (VDD). It is therefore found that the discontinuity of a high-frequency signal, conventionally occurring in the control of the gate input voltage and the drain/source input voltage of FETs shown in FIG. 14E, has been eliminated as shown in FIG. 7E.

In other words, in Embodiment 3, as in Embodiment 1, a high-frequency switch circuit free from discontinuity of a high-frequency signal, which may otherwise occur at the time of ON/OFF switching of the booster circuit (CP) 13, can be implemented by providing a means for giving a delay time to the gate input voltage and the drain/source input voltage.

Also, in this configuration, it is possible to shift the delay times in the gate input voltage and the drain/source input voltage given at the time of switching of the booster circuit 13 from ON to OFF. by changing the design of the delay circuits incorporated in the first and second delay circuit-incorporated voltage switch circuits (TDSW) 17 and 18.

In this embodiment, by designing the delay time of the delay circuit in the first delay circuit-incorporated voltage switch circuit (TDSW) 17 to be longer than the delay time of the delay circuit in the second delay circuit-incorporated voltage switch circuit (TDSW) 18, it is possible to produce a delay between the FET gate input voltage V101 and the FET drain/source input voltage V102 at the time of switching of the booster circuit 13 from ON to OFF, that is, at the time when the FET voltage is switched from the booster circuit output voltage V103 (for example, boosted voltage VCP=7 V) to the external supply voltage V11 (for example, power supply voltage VDD=3 V). For example, assume that the delay circuit shown in FIG. 4A using a time constant obtained from R1 and C1 is used as the delay circuits in this embodiment. When it is desired to delay the gate input voltage V101 compared with the drain/source input voltage V102, the time constant of the delay circuit in the first delay circuit-incorporated voltage switch circuit (TDSW) 17 may be set larger than the time constant of the delay circuit in the second delay circuit-incorporated voltage switch circuit (TDSW) 18.

In Embodiment 3, in which separate delay circuit-incorporated voltage switch circuits are connected to the gate terminals and drain/source terminals of the FETs, the delay times in the gate input voltage and the drain/source input voltage can be controlled individually. Thus, designing with margins against variations and the like can be further provided compared with Embodiments 1 and 2.

### Embodiment 4

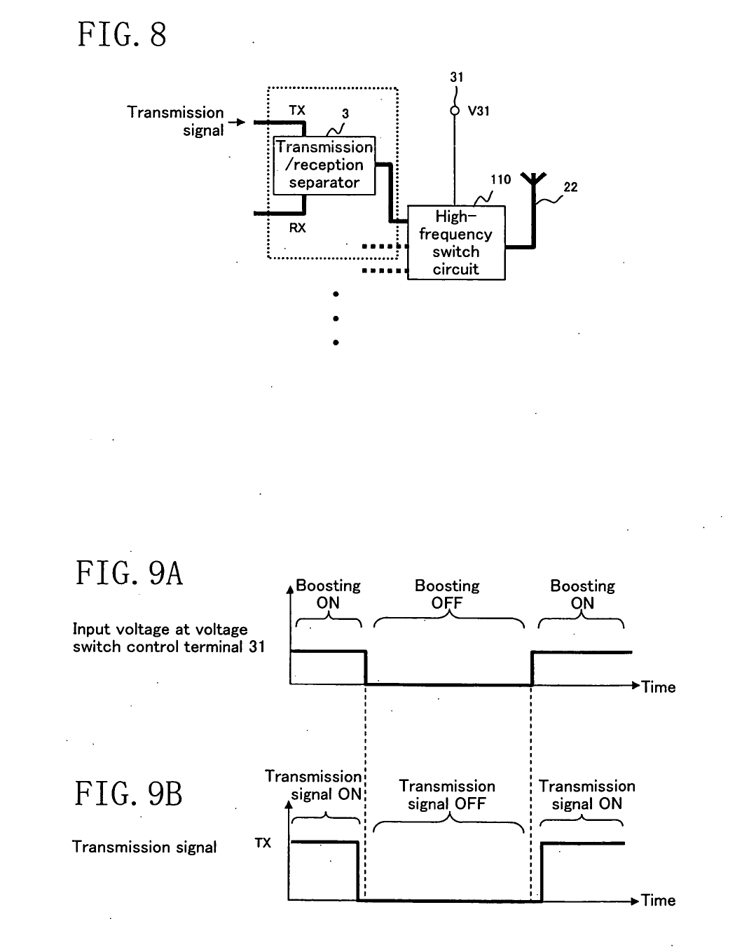

FIG. 8 is a circuit diagram of a communication terminal apparatus of Embodiment 4 of the present invention. In FIG. 8, part of a radio circuit of the communication terminal apparatus is shown.

In Embodiment 4, described is a communication terminal apparatus useful when two kinds of power different in magnitude, such as a transmission signal and a reception signal, like those used in a CDMA scheme are handled on one ON path simultaneously.

As shown in FIG. 8, the communication terminal apparatus of Embodiment 4 includes: a transmission/reception separator 3; a high-frequency switch circuit 110 to which the transmission/reception separator 3 is connected; an antenna 22 connected to the high-frequency switch circuit 110; and a voltage switch control terminal 31 connected to the high-frequency switch circuit 110. The high-frequency switch circuit (ANTSW) 110, which switches connections between the antenna 22 and the transmission/reception separator (DUP) 3 and paths in other frequency bands to each other, is a booster circuit-incorporated high-frequency switch that can control ON/OFF of the booster circuit with the voltage switch control terminal 31. As the high-frequency switch circuit (ANTSW) 110, any of those of Embodiments 1 to 3 described above may be used, to allow changes of the gate input voltage and the drain/source input voltage according to the timing charts at the time of ON/OFF switching of the booster circuit, and thus eliminate discontinuity of a high-frequency signal at the time of ON/OFF switching of the booster circuit.

The operation of the communication terminal apparatus of Embodiment 4 will be described. FIGS. 9A and 9B are timing charts of the input voltage at the voltage switch control terminal 31 and a transmission signal TX. From FIGS. 9A and 9B, it is found that in the communication terminal apparatus of Embodiment 4, the transmission signal TX is OFF reliably during the time when the voltage switch control terminal 31 for the high-frequency switch circuit is OFF, that is, when the booster circuit is OFF. In other words, it is found that the voltage switch control terminal 31 is switched to OFF after the transmission signal TX is turned to OFF. Also, it is found that since the transmission signal TX is turned to ON after the booster circuit is switched to ON, the booster circuit is ON reliably during the time when the transmission signal TX is ON. Thus, in the high-frequency switch circuit (ANTSW) 110, it is ensured that the boosted voltage can be supplied to the FETs during signal transmission in which distortion should desirably be suppressed.

The high-frequency switch circuit (ANTSW) 110 and the transmission/reception separator (DUP) 3 may be integrated into a same package. This will further contribute to reduction of the size of the transmission terminal apparatus.

### Embodiment 5

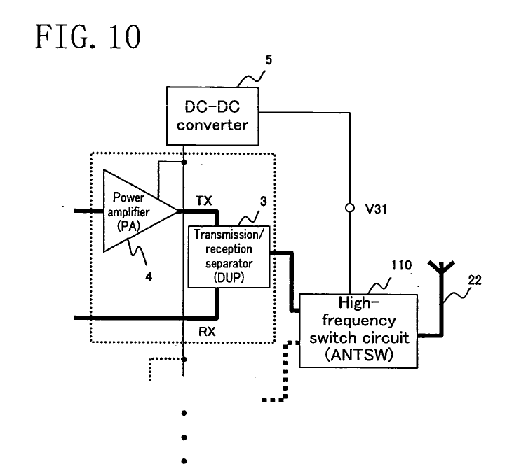

FIG. 10 is a circuit diagram of a communication terminal apparatus of Embodiment 5 of the present invention. The antenna 22, the high-frequency switch circuit (ANTSW) 110 and the transmission/reception separator (DUP) 3 in FIG. 10 that are the same in function as those in FIG. 8 are denoted by the same reference numerals. In the communication terminal apparatus of Embodiment 5, a power amplifier (PA) 4 for amplifying a transmission signal is connected to the transmission/reception separator 3, and a DC-DC converter for supplying a voltage to the power amplifier (PA) 4 is connected to the voltage switch control terminal 31 for the high-frequency switch circuit (ANTSW) 110.

In the communication terminal apparatus of Embodiment 5, the voltage switch control terminal 31 for the high-frequency switch circuit 110 is controlled with the DC-DC converter 5 that supplies a voltage to the power amplifier (PA) 4 for a transmission signal. In this way, the power amplifier (PA) 4 and the voltage switch circuit of the high-frequency switch circuit 110 can be controlled with the same control system.

Thus, according to the communication terminal apparatus of this embodiment, in which the power amplifier (PA) 4 and the voltage switch circuit of the high-frequency switch circuit 110 can be controlled with the same DC-DC converter 5, the external control system can be reduced. In addition, it becomes easy to implement the timing charts of the voltage at the voltage switch control terminal 31 and the transmission signal TX shown in FIGS. 9A and 9B.

The high-frequency switch circuit (ANTSW) 110, the transmission/reception separator (DUP) 3, the power amplifier (PA) 4 and the DC-DC converter 5 may be integrated into a same package. This will further contribute to reduction of the size of the transmission terminal apparatus.

### Embodiment 6

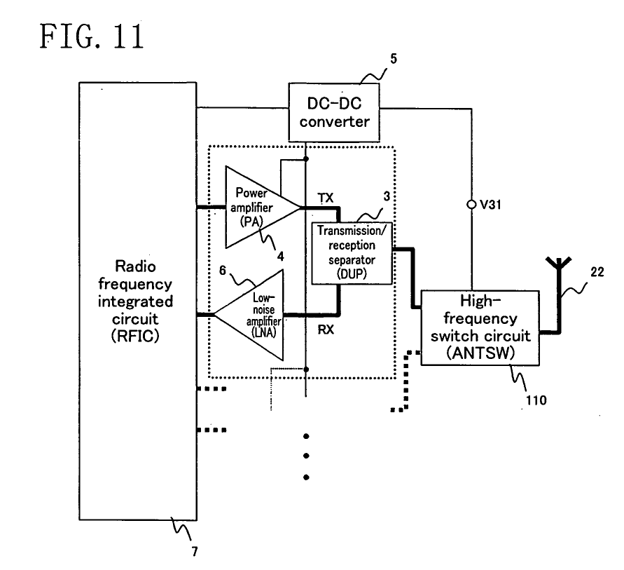

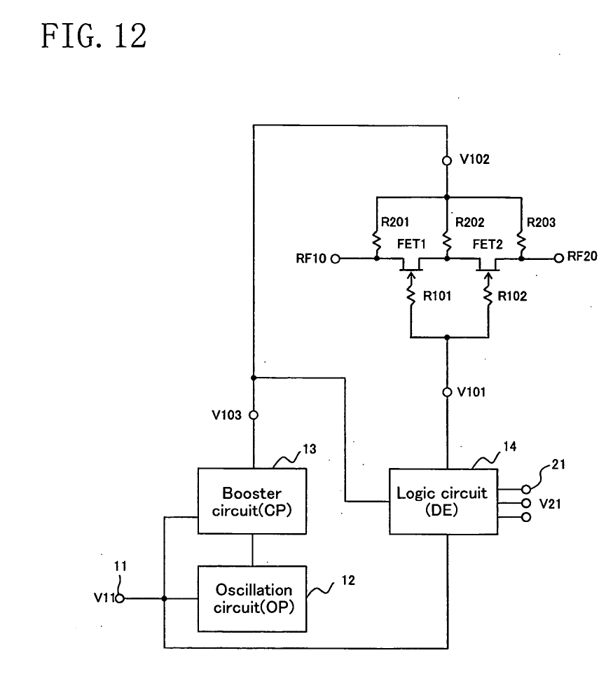

FIG. 11 is a circuit diagram of a communication terminal apparatus of Embodiment 6 of the present invention. The communication terminal apparatus of Embodiment 6 is different from the communication terminal apparatus of Embodiment 5 shown in FIG. 10 in that a low-noise amplifier (LNA) 6 for amplifying a transmission signal is connected to the transmission/reception separator 3 and that a radio frequency integrated circuit (RFIC) 7 for high-frequency signal processing is connected to the power amplifier (PA) 4 and the low-noise amplifier (LNA) 7. The high-frequency switch circuit (ANTSW) 110, the transmission/reception separator (DUP) 3, the power amplifier (PA) 4, the DC-DC converter 5, the low-noise amplifier (LNA) 6 and the radio frequency integrated circuit (RFIC) 7 may be integrated into a same package. This will further contribute to reduction of the size of the transmission terminal apparatus.

### Other Embodiments

While the present invention has been described in preferred embodiments, it will be apparent to those skilled in the art that the disclosed invention is not limited to the embodiments described above, but may also include forms as follows.

In Embodiments 1 to 3, the high-frequency switch circuit constitutes a one-input, one-output SPST switch. The numbers of input terminals and output terminals of the high-frequency switch circuit are not limited to this. Naturally, the present invention also encompasses a semiconductor circuit device constituting a multi-input, multi-output high-frequency switch circuit.

In Embodiments 1 to 3, the series of FETs as a switch circuit provided on a high-frequency signal path is composed of two FETs. The present invention is not limited to this, but the series of FETs may be composed of one FET, composed of three or more FETs or composed of a multi-gate FET. These cases also fall in the scope of the present invention.

The FETs in Embodiments 1 to 3 may be gallium arsenide field effect transistors.

In Embodiments 1 to 3, only the circuit configurations of the high-frequency switch circuit were described. Such circuit configurations may be implemented by integrating part or all of the components constituting the high-frequency switch circuit on a semiconductor substrate, or otherwise integrating them into a same package.

In Embodiments 4 to 6, only the configurations of the communication terminal apparatus were described. Such circuit configurations may be implemented by integrating part or all of the components constituting the communication terminal apparatus on a semiconductor substrate, or otherwise integrating them into a same package.

It should also be noted that any combination of the embodiments described above and other embodiments will fall in the scope of the present invention.

What is claimed is:

1. A high-frequency switch circuit comprising:
a series of field effect transistors having a plurality of field effect transistors connected in series between input/output terminals of a high-frequency signal path permitting passing of a plurality of high-frequency signals different in frequency, a control voltage input terminal connected to gates of the plurality of field effect transistors to permit input of a control input signal for controlling ON/OFF of the plurality of field effect transistors, and a potential fixing connection terminal connected to drains and sources of the plurality of field effect transistors for fixing potentials at the drains and sources of the plurality of field effect transistors;
an oscillation circuit for oscillating an input external supply voltage;
a booster circuit for boosting the external supply voltage supplied from the oscillation circuit; and
a voltage selection circuit for switching a boosted voltage boosted with the booster circuit and a non-boosted voltage free from boosting with the booster circuit to each other and outputting the resultant voltage to the control voltage input terminal and the potential fixing connection terminal,
wherein the voltage selection circuit has means for delaying voltage drop at the control voltage input terminal and the potential fixing connection terminal at the time of switching from the boosted voltage to the non-boosted voltage.

2. The high-frequency switch circuit of claim 1, wherein the means for delaying voltage drop is means in which the voltage drop at the control voltage input terminal and the potential fixing connection terminal is allowed to occur gradually over a given voltage drop time.

3. The high-frequency switch circuit of claim 2, wherein the means for delaying voltage drop is a RC delay circuit for outputting a delay signal delayed according to a time constant of a RC time constant circuit composed of a resistance and a capacitance.

4. The high-frequency switch circuit of claim 2, wherein the means for delaying voltage drop is a gate delay circuit composed of gate delay of a semiconductor device.

5. The high-frequency switch circuit of claim 1, wherein the means for delaying voltage drop is means in which the voltage drop at the control voltage input terminal and the potential fixing connection terminal is allowed to occur with a given delay time.

6. The high-frequency switch circuit of claim 5, wherein the voltage selection circuit comprises a first voltage selection circuit and a second voltage selection circuit,
the first voltage selection circuit has first delay means for delaying voltage drop at the control voltage input terminal,
the second voltage selection circuit has second delay means for delaying voltage drop at the potential fixing connection terminal, and
a delay time with the first delay means is greater than a delay time with the second delay means.

7. The high-frequency switch circuit of claim 6, wherein the first and second delay means are RC delay circuits for outputting a delay signal delayed according to a time constant of a RC time constant circuit composed of a resistance and a capacitance.

8. The high-frequency switch circuit of claim 6, wherein the first and second delay means are gate delay circuits composed of gate delay of a semiconductor device.

9. The high-frequency switch circuit of claim 1, wherein the series of field effect transistors is constructed of a plurality of multi-gate field effect transistors.

10. The high-frequency switch circuit of claim 1, wherein the series of field effect transistors is constructed of a plurality of gallium arsenic field effect transistors.

11. A semiconductor device comprising the high-frequency switch circuit of claim 1 integrated on one semiconductor substrate.

12. A semiconductor device comprising the high-frequency switch circuit of claim 1 integrated into one package.

13. A communication terminal apparatus comprising:
the high-frequency switch circuit of claim 1; and
a transmission/reception separator connected to the high-frequency switch circuit,
wherein the transmission/reception separator switches transmission and reception of a signal to and from the high-frequency switch circuit to each other.

14. The communication terminal apparatus of claim 13, further comprising:
a power amplifier connected to the transmission/reception separator; and
a DC-DC converter for supplying a voltage to the power amplifier,
wherein the power amplifier amplifies power of a signal transmitted to the transmission/reception separator, and
the high-frequency switch circuit is voltage-controlled with the DC-DC converter.

15. The communication terminal apparatus of claim 14, further comprising:
a low-noise amplifier connected to the transmission/reception separator; and
a radio frequency integrated circuit connected to the power amplifier and the low-noise amplifier.

16. The communication terminal apparatus of claim 15, wherein at least two of the high-frequency switch circuit, the transmission/reception separator, the power amplifier, the DC-DC converter, the low-noise amplifier and the radio frequency integrated circuit are mounted on one semiconductor substrate.

17. The communication terminal apparatus of claim 15, wherein at least two of the high-frequency switch circuit, the transmission/reception separator, the power amplifier, the DC-DC converter, the low-noise amplifier and the radio frequency integrated circuit are integrated into one package.

18. The communication terminal apparatus of claim 13, wherein at switching of the booster circuit from ON to OFF, a transmission signal input into the high-frequency switch circuit from the transmission/reception separator is switched to OFF before the booster circuit is switched to OFF, and
at switching of the booster circuit from OFF to ON, the transmission signal input into the high-frequency switch circuit from the transmission/reception separator is switched to ON after the booster circuit is switched to ON.

19. A high-frequency switch circuit comprising:
a series of field effect transistors having a plurality of field effect transistors connected in series between input/output terminals of a high-frequency signal path permitting passing of a plurality of high-frequency signals different in frequency, a control voltage input terminal connected to gates of the plurality of field effect transistors to permit input of a control input signal for controlling ON/OFF of the plurality of field effect transistors, and a potential fixing connection terminal connected to drains and sources of the plurality of field effect transistors to fix potentials at the drains and sources of the plurality of field effect transistors;
an external supply voltage input terminal at which an external supply voltage is supplied;
an oscillation circuit for oscillating the external supply voltage supplied from the external supply voltage input terminal;
a booster circuit connected to the control voltage input terminal and the potential fixing connection terminal for boosting the external supply voltage supplied from the oscillation circuit;
a voltage switch control terminal receiving a signal for switching the oscillation circuit to OFF at the time of switching of the booster circuit from ON to OFF; and
a diode connected between the booster circuit and the external supply voltage input terminal.

20. The high-frequency switch circuit of claim 19, wherein the series of field effect transistors is constructed of a plurality of multi-gate field effect transistors.

21. The high-frequency switch circuit of claim 19, wherein the series of field effect transistors is constructed of a plurality of gallium arsenic field effect transistors.

22. A semiconductor device comprising the high-frequency switch circuit of claim 19 integrated on one semiconductor substrate.

23. A semiconductor device comprising the high-frequency switch circuit of claim 19 integrated into one package.

24. A communication terminal apparatus comprising:
the high-frequency switch circuit of claim 19; and
a transmission/reception separator connected to the high-frequency switch circuit,
wherein the transmission/reception separator switches transmission and reception of a signal to and from the high-frequency switch circuit to each other.

25. The communication terminal apparatus of claim 24, further comprising:
a power amplifier connected to the transmission/reception separator; and
a DC-DC converter for supplying a voltage to the power amplifier,
wherein the power amplifier amplifies power of a signal transmitted to the transmission/reception separator, and
the high-frequency switch circuit is voltage-controlled with the DC-DC converter.

26. The communication terminal apparatus of claim 25, further comprising:
a low-noise amplifier connected to the transmission/reception separator; and
a radio frequency integrated circuit connected to the power amplifier and the low-noise amplifier.

27. The communication terminal apparatus of claim 26, wherein at least two of the high-frequency switch circuit, the transmission/reception separator, the power amplifier, the DC-DC converter, the low-noise amplifier and the radio frequency integrated circuit are mounted on one semiconductor substrate.

28. The communication terminal apparatus of claim 26, wherein at least two of the high-frequency switch circuit, the transmission/reception separator, the power amplifier, the DC-DC converter, the low-noise amplifier and the radio frequency integrated circuit are integrated into one package.

29. The communication terminal apparatus of claim 24, wherein at switching of the booster circuit from ON to OFF, a transmission signal input into the high-frequency switch circuit from the transmission/reception separator is switched to OFF before the booster circuit is switched to OFF, and
at switching of the booster circuit from OFF to ON, the transmission signal input into the high-frequency switch circuit from the transmission/reception separator is switched to ON after the booster circuit is switched to ON.
